(19) United States
(12) Patent Application Publication
(10) Pub. No.: US 2024/0008374 A1
(43) Pub. Date: Jan. 4, 2024

(54) VERTICAL ULTRA-THIN PCM CELL

(71) Applicant: INTERNATIONAL BUSINESS MACHINES CORPORATION, Armonk, NY (US)

(72) Inventors: Kevin W. Brew, Niskayuna, NY (US); Timothy Mathew Philip, Albany, NY (US); JIN PING HAN, Yorktown Heights, NY (US); Ching-Tzu Chen, Ossining, NY (US); Injo Ok, Loudonville, NY (US)

(21) Appl. No.: 17/855,131

(22) Filed: Jun. 30, 2022

(51) Int. Cl. H01L 45/00; H01L 27/24

(52) U.S. Cl. CPC H01L 45/06; H01L 27/24; H01L 45/1675; H01L 45/144; H01L 45/1616; H01L 45/1253

(57) ABSTRACT

Memory cells and methods of forming the same include forming a hole in an interlayer dielectric to expose an end of a conductive top electrode. A phase change material is conformally deposited on surfaces of the hole. A remaining portion of the hole is filled with a dielectric material after conformally depositing the phase change material.

### BACKGROUND

The present invention generally relates to semiconductor device fabrication, and, more particularly, to semiconductor devices that feature reduced reset currents.

Phase change material (PCM) cells can be used to store information in a device. The resistance of a PCM cell may be changed by applying heat that causes a partial or complete change in the phase of the PCM cell. While the resistance can be changed in one direction (e.g., decreased) in a continuous fashion, changing the resistance in the opposite direction is accomplished all at once with a reset operation. This reset operation may use a higher current than incremental resistance changes.

### SUMMARY

A method of forming a memory cell includes forming a hole in an interlayer dielectric to expose an end of a conductive top electrode. A phase change material is conformally deposited on surfaces of the hole. A remaining portion of the hole is filled with a dielectric material after conformally depositing the phase change material.

A semiconductor device includes a dielectric layer having a depression in a top surface of the dielectric layer. A phase change material layer is on a surface of the depression. A dielectric structure on the phase change material layer fills the depression. A first electrode is in electrical contact with phase change material layer. A second electrode is in electrical contact with the phase change material layer.

A memory cell includes a phase change material liner beneath, and laterally surrounding, a dielectric core. A dielectric layer is around the phase change material liner. A first electrode is in electrical contact with phase change material layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a memory device that includes a thin phase change material (PCM) layer with localized heating, in accordance with an embodiment of the present invention;

FIG. 2 is a set of views of a step in the formation of a memory device, including a top-down view and a cross-sectional view, that shows a bottom electrode formed in a substrate, in accordance with an embodiment of the present invention;

FIG. 3 is a set of views of a step in the formation of a memory device, including a top-down view and a cross-sectional view, that shows conductive wires being formed in a dielectric layer over the bottom electrode, in accordance with an embodiment of the present invention;

FIG. 4 is a set of views of a step in the formation of a memory device, including a top-down view and a cross-sectional view, that shows a hole formed in the dielectric layer to expose the bottom electrode, in accordance with an embodiment of the present invention;

FIG. 5 is a set of views of a step in the formation of a memory device, including a top-down view and a cross-sectional view, that shows the formation of a thin PCM layer and a dielectric plug in the hole, in accordance with an embodiment of the present invention;

FIG. 6 is a set of views of a step in the formation of a memory device, including a top-down view and a cross-sectional view, that shows the formation of electrical contacts to the electrodes, in accordance with an embodiment of the present invention;

FIG. 7 is a top-down view of a memory device that includes a thin phase change material (PCM) layer with localized heating and a single side electrode, in accordance with an embodiment of the present invention;

FIG. 8 is a cross-sectional view of an embodiment of a memory device that includes an underlying thermal sink structure, in accordance with an embodiment of the present invention;

FIG. 9 is a top-down view of a memory device that includes a thin PCM layer and stacked side electrodes, in accordance with an embodiment of the present invention;

FIG. 10 is a set of views of a step in the formation of a memory device, including a top-down view and a cross-sectional view, that shows the formation of a bottom electrode on a bottom wire, in accordance with an embodiment of the present invention;

FIG. 11 is a set of views of a step in the formation of a memory device, including a top-down view and a cross-sectional view, that shows the formation of top electrode on over the bottom wire, in accordance with an embodiment of the present invention;

FIG. 12 is a set of views of a step in the formation of a memory device, including a top-down view and a cross-sectional view, that shows the formation of a thin PCM layer in a hole contacting the top electrode and the bottom electrode, in accordance with an embodiment of the present invention;

FIG. 13 is a set of views of a step in the formation of a memory device, including a top-down view and a cross-sectional view, that shows the formation of a top wire in electrical contact with the top electrode, in accordance with an embodiment of the present invention;

FIG. 14 is a block/flow diagram of a method of reading a resistance state of a PCM device, in accordance with an embodiment of the present invention;

FIG. 15 is a block/flow diagram of a method of incrementally changing a resistance state of a PCM device, in accordance with an embodiment of the present invention;

FIG. 16 is a block/flow diagram of a method of resetting a resistance state of a PCM device, in accordance with an embodiment of the present invention;

FIG. 17 is a block/flow diagram of a method of forming a PCM device with electrodes on opposing sides of a PCM layer, in accordance with an embodiment of the present invention;

FIG. 18 is a block/flow diagram of a method of forming a PCM device with stacked electrodes, in accordance with an embodiment of the present invention; and

FIG. 19 is a cross-sectional view of an embodiment of a memory device that includes a top electrode, in accordance with an embodiment of the present invention.

### DETAILED DESCRIPTION

Phase change material (PCM) cells may be formed using a thin layer of PCM, for example formed conformally on a sidewall of a structure. Multiple electrical contacts may be formed to the thin PCM layer, defining a region of relatively high current flux, which may define a region where amorphization of the PCM may occur. The thin layer of PCM reduces the amount of current needed to heat the PCM to reset the resistance. In addition, this approach to PCM cell fabrication improves size uniformity of the contact areas and provides the ability to tune device resistance using the dimensions of the PCM layer, rather than by doping.

PCMs may include materials where two distinct solid phases of matter are available within the operating conditions of the device. For example, the PCM may be able to stably occupy an amorphous phase and a crystalline phase at a given temperature and pressure. For a PCM, the resistivities of these two phases may differ, for example with the amorphous state having a higher resistivity than the crystalline state. Within a given PCM cell, the two phases may coexist in differing proportions. For example, a PCM cell that is entirely in the amorphous state may have a first resistance, a PCM cell that is entirely in the crystalline state may have a second resistance, and a PCM cell that is partially in the amorphous state and partially in the crystalline state may have a third resistance that is between the first resistance and the second resistance.

During operation, the PCM cell may start in the amorphous state. To reduce the resistance of the PCM cell, a first current pulse may be applied to the PCM cell. The first current pulse may provide enough energy to change the phase of the PCM from the amorphous phase to the crystalline phase. This change may be performed incrementally, with each pulse changing the phase of a portion of the PCM, until the entire PCM has changed to the crystalline phase.

To reverse the change of the resistance, a reset current pulse may be applied. The reset current pulse may generate enough heat to reset the entire PCM to the amorphous phase. The reset current pulse may generally be larger than the magnitude of the first current pulse, and may depend on properties of the PCM, such as the thickness of the layer of PCM. The current flux may be increased due to the relatively small contact area of the side-contact heater. Thus, by using a thin PCM layer as the PCM cell, the magnitude of the reset current pulse can be reduced. The resistance may be tuned by adjusting the dimensions of the contact, and the side-contact structure provides good thermal isolation between devices.

Referring now to FIG. 1, a top-down view of an exemplary PCM device is shown. The device includes a PCM layer 102 formed around a dielectric structure 104. A set of wires 106 are connected to the PCM layer 102 by electrodes 108. At the interface of each electrode 108 with the PCM layer 102, a current may pass through the PCM layer 102 to affect the resistance of that portion of the PCM layer 102. The current passes to a bottom electrode, not visible in this view, which may be positioned underneath the PCM layer 102. A dielectric material 112 fills the spaces between the wires 106 and the electrodes 108, providing electrical isolation. The structure as shown may store six distinct resistance values, one at each interface between an electrode 108 and the PCM layer 102.

A cross-sectional plane AA is indicated. Subsequent views will show both top-down and cross-sectional views of steps in the fabrication of PCM devices. As used herein, the terms “electrode” and “wire” may be used interchangeably, as both refer to conductive structures.

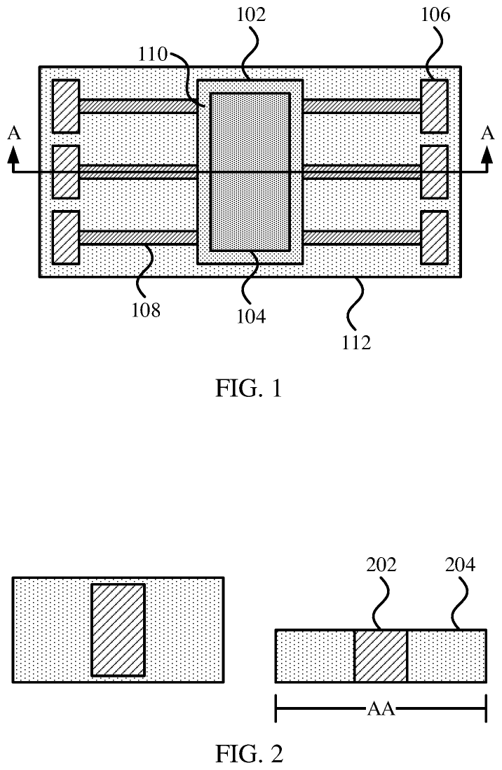

Referring now to FIG. 2, a set of views of a step in the formation of a PCM device is shown. The left shows a top-down view, while the right shows a cross-sectional view along plane AA. A bottom electrode 202 is shown, formed in a layer of dielectric material 204. The bottom electrode 202 may be formed from any appropriate conductive material, such as tungsten, nickel, titanium, molybdenum, tantalum, copper, platinum, silver, gold, ruthenium, iridium, rhenium, rhodium, cobalt, and alloys thereof, and conductive composite materials such as tantalum nitride and titanium nitride. The dielectric layer 204 may be formed from any appropriate electrically insulating material, such as silicon dioxide or silicon nitride.

The bottom electrode 202 may be formed by, e.g., etching a trench in the dielectric layer 204 and then depositing a conductive material to fill the trench. The trench may be formed by, e.g., establishing a pattern mask using any appropriate photolithographic process, followed by a selective anisotropic etch that uses the pattern mask to block the etch in regions outside of the trench. The conductive material may be deposited using any appropriate conformal or directional deposition process, followed by a chemical mechanical planarization (CMP) process that exposes the top surface of the dielectric layer 204.

Reactive Ion Etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

The conductive material of the bottom electrode 202 may be formed by any appropriate process including, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

CMP is performed using, e.g., a chemical or granular slurry and mechanical force to gradually remove upper layers of the device. The slurry may be formulated to be unable to dissolve, for example, the work function metal layer material, resulting in the CMP process's inability to proceed any farther than that layer.

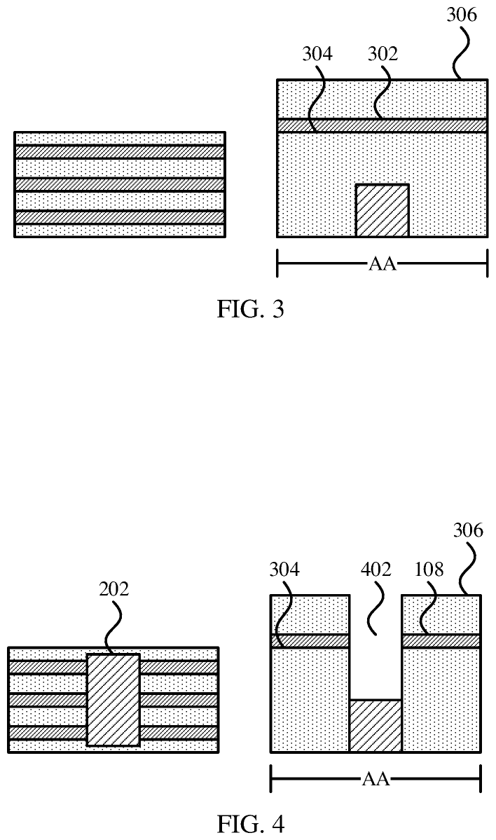

Referring now to FIG. 3, a set of views of a step in the formation of a PCM device is shown. The left shows a top-down view, while the right shows a cross-sectional view along plane AA. This top-down view omits a top portion of dielectric layer 306 to illustrate the positioning of the wires 302 underneath.

As shown in the cross-sectional view, additional dielectric material 304 is deposited over the bottom electrode 202. This new dielectric material 304 may be formed from the same electrically insulating material as the first dielectric layer 204 or may be a different dielectric material. Any appropriate deposition process may be used, such as CVD.

Any appropriate number of conductive wires 302 may then be formed over the new dielectric material 304, for example by depositing a layer of conductive material and then patterning the layer of conductive material to form wires. Any appropriate deposition method, such as CVD, may be used to deposit the conductive material. A top layer of dielectric material 306 may then be deposited over the wires 302 using any appropriate process, such as CVD. The conductive wires 302 may have any appropriate thickness, for example between about 5 nm and about 50 nm.

Referring now to FIG. 4, a set of views of a step in the formation of a PCM device is shown. The left shows a top-down view, while the right shows a cross-sectional view along plane AA. This top-down view omits a top portion of dielectric layer 306 to illustrate the positioning of the electrodes 108 underneath.

A hole 402 is etched down, through the dielectric layers 304 and 306 and through the wires 302 to expose the bottom electrode 202. Although the hole 402 is shown as having similar dimensions to the bottom electrode 202, it should be understood that the bottom electrode 202 may be wider or narrower than the hole 402.

The wires 302 are separated into contact electrodes 108, with a set of wires on each side of the hole 402. In this example the three wires 302 are separated into six contact electrodes 108. Any appropriate number of such contact electrodes 108 may be formed in this manner. In some embodiments, as described in greater detail below, the hole 402 may be positioned at one end of the wires 302, such that the wires 302 are not split into halves. In such embodiments, an odd number of contact electrodes 108 may be formed.

The etch may be performed using any appropriate selective anisotropic etch that removes material from the dielectric layers but that does not substantially damage the bottom electrode 202. Alternatively, multiple distinct etches may be performed, including a first etch to expose the wires 302, a second etch to remove the exposed material of the wires 302, and a third etch to expose the bottom electrode 202. Using multiple etches can promote selectivity between the final etch and the bottom electrode 202, where a single etch might remove too much of the conductive material of the bottom electrode 202.

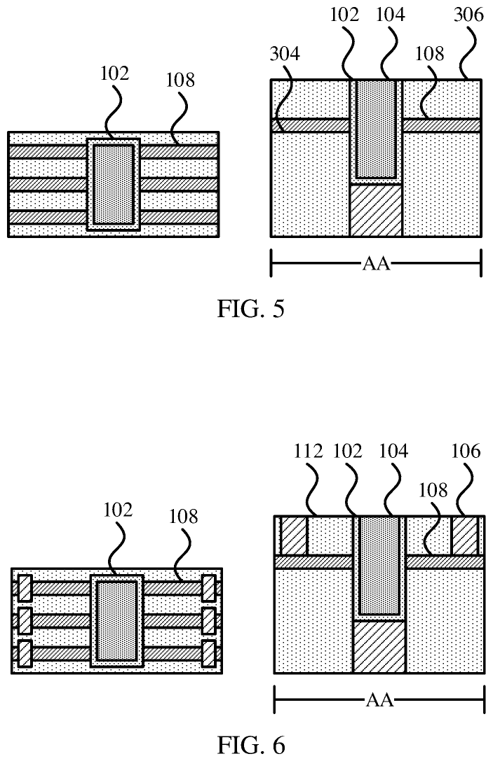

Referring now to FIG. 5, a set of views of a step in the formation of a PCM device is shown. The left shows a top-down view, while the right shows a cross-sectional view along plane AA. This top-down view omits a top portion of dielectric layer 306 to illustrate the positioning of the electrodes 108 underneath.

A layer of PCM 102 is conformally deposited in the hole 402. It is contemplated that the layer of PCM 102 may be deposited to a thickness between about 2 nm to about 50 nm, but it should be understood that other thicknesses may be used instead. The PCM layer 102 may be formed from any appropriate material, such as GeSbTe in any appropriate proportions, SiGeSbTe in any appropriate proportions, Sb₂Te₃, GeTe, and Cr₂Ge₂Te₆. In some cases the PCM layer 102 may be doped, such as with nitrogen, while in other embodiments the PCM layer 102 may be undoped. The dielectric structure 104 may be formed from a dielectric material that is distinct from, e.g., the top dielectric layer 306, and may be deposited using any appropriate deposition process to fill the hole 402. The dielectric structure 104 may be formed from, e.g., silicon nitride or a high-k dielectric material. After deposition of the PCM material and the dielectric material, a CMP process may be performed to expose the top dielectric layer 306, with the CMP process stopping on the material of the top dielectric layer 306.

Referring now to FIG. 6, a set of views of a step in the formation of a PCM device is shown. The left shows a top-down view, while the right shows a cross-sectional view along plane AA. This top-down view omits a top portion of dielectric layer 306 to illustrate the positioning of the electrodes 108 underneath.

As can be seen from this view, the contact area between the side electrodes 106 and the PCM layer 102 may be small relative to the contact area between the underlying bottom electrode 202 and the PCM layer 102. The lower thermal conductivity of smaller electrodes 106 localizes heat in the PCM layer 20 around the smaller electrodes 106. This decreases the chance that heat will localize between the electrodes, causing amorphized PCM to occur further away from the electrodes, which could result in current finding alternative paths through the PCM layer 102. Localizing amorphization increases the predictability in resistance changes in the PCM layer 102. The contact dimension between small electrodes 106 and the PCM layer 102 may be in a range between about and about 20 nm, while the contact dimension between the bottom electrode 202 and the PCM layer 102 may be between about 20 nm and about 500 nm, in either dimension. It is specifically contemplated that the contact area between the larger electrode and the PCM layer 102 may be greater than about twice that of the contact area between the smaller electrode(s) and the PCM layer 102.

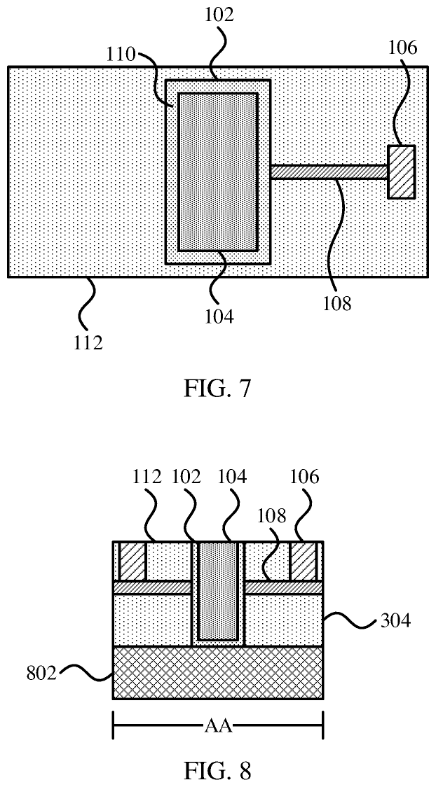

Referring now to FIG. 7, a top-down view of an alternative embodiment is shown. Rather than cutting the conductive wires 302 into distinct pieces as shown in FIG. 4, the hole 402 may be positioned at an end of the wires 302. In this embodiment, a single PCM cell is formed with a single contact electrode 108 and a single contact wire 106.

Referring now to FIG. 8, a cross-sectional view of an alternative embodiment, along plane AA, is shown. Some embodiments may include a symmetric cell with dual heaters, for dual-polarity read-write operations. In such embodiments, the bottom electrode may be replaced by a thermal sink layer 802. The thermal sink layer 802 may be formed from a material having a high thermal conductivity or from a floating metal layer. Exemplary materials that may be used for the thermal sink layer 802 may include, for example, aluminum nitride, tungsten, copper, titanium nitride, tantalum nitride, and alloys thereof.

The thermal sink layer 802 normalizes the temperature of the PCM layer 102 near its surface. As a result, the portions of the PCM layer 102 closer to the electrodes 108 will experience higher temperatures during a reset operation, while the portions closer to the thermal sink layer 802 will remain relatively cool. This can limit the region that returns to an amorphous state to the area around the electrodes 108, which can make the resistance of the device easier to control.

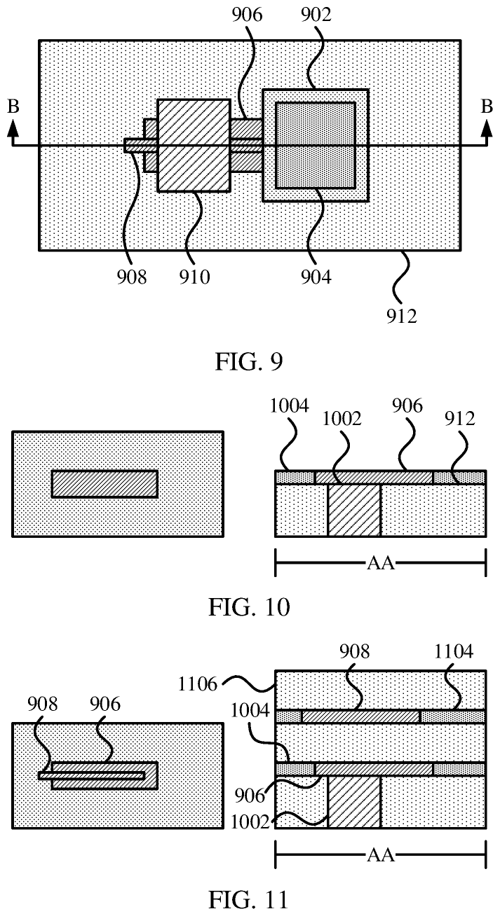

Referring now to FIG. 9, a top-down view of an exemplary PCM device is shown. Some embodiments may make use of a vertically stacked arrangement of contacts. As above, a thin PCM layer 902 is formed around a dielectric structure 904. A top wire 910 is connected to the thin PCM layer 902 by a top electrode 908, while a bottom contact (not shown in this view) is connected to the thin PCM layer 902 by a bottom electrode 906. In this view, upper layers of dielectric material are not shown, to reveal the underlying structures. A passivating lower dielectric layer 912 is shown, at the level of the bottom electrode.

Referring now to FIG. 10, a set of views of a step in the formation of a PCM device is shown. The left shows a top-down view, while the right shows a cross-sectional view along plane BB. A bottom wire 1002 is shown, which is formed within the lower dielectric layer 912 and which may be formed from any appropriate dielectric material. A lower hardmask dielectric layer 1004 is formed on the lower dielectric layer, for example from silicon nitride, which may be patterned by any appropriate photolithographic technique to expose the bottom wire 1002. A lower contact electrode 906 is then formed to make electrical contact with the bottom wire 1002, for example depositing conductive material by any appropriate deposition process and then polishing the conductive material down to the level of the hardmask dielectric layer 1004 using a CMP process.

Referring now to FIG. 11, a set of views of a step in the formation of a PCM device is shown. The left shows a top-down view, while the right shows a cross-sectional view along plane BB. Additional dielectric material is formed over the lower contact electrode 906 by any appropriate process. An upper hardmask dielectric 1104 is patterned and an upper contact electrode 908 is formed in the opening created by the patterning process. The upper hardmask dielectric 1104 may be formed from silicon nitride and the upper contact electrode 908 may be formed from any appropriate conductive material. A top layer of dielectric material 1106 may be added over the upper contact electrode 908.

In the top-down view, the dielectric material 1106 is not shown, to illustrate the relationship of the upper contact electrode 908 and the lower contact electrode 906. In some embodiments, the upper contact electrode 908 may be narrower than the lower contact electrode 906, to tune the properties of the PCM device by controlling the current flux at the interface between the upper contact electrode 908 and the PCM layer. In some embodiments, the lower contact electrode 906 may be made narrower than the upper contact electrode 908, or the wires may be made with the same cross-sectional dimensions.

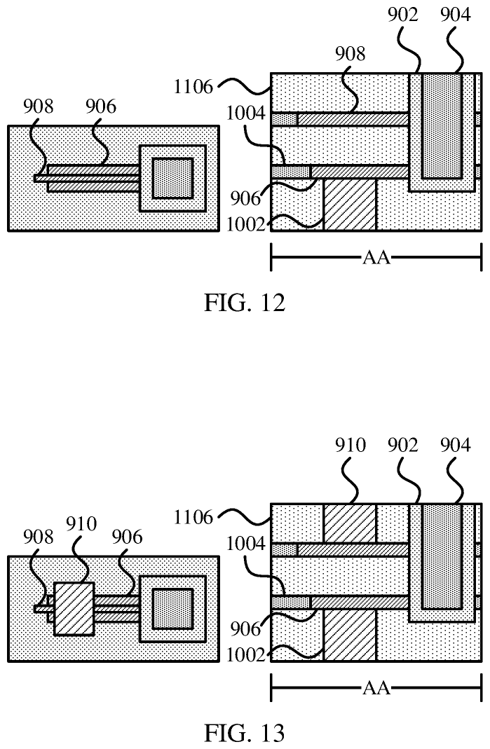

Referring now to FIG. 12, a set of views of a step in the formation of a PCM device is shown. The left shows a top-down view, while the right shows a cross-sectional view along plane BB. A hole is etched into the surface, penetrating down to expose the upper contact electrode 908 and the lower contact electrode 906. The hole may be etched using any appropriate anisotropic etch. One or more such etches may be performed, for example using a timed non-selective etch or a set of selective etches.

PCM material is formed in the hole by any appropriate conformal deposition process, such as CVD. New dielectric material is then used to fill the remaining space in the hole, from a dielectric material that is distinct from the top layer of dielectric material 1106. PCM material and the new dielectric material may then be polished down using a CMP process that stops on the material of the top dielectric layer 1106, leaving PCM layer 902 and dielectric structure 904.

Referring now to FIG. 13, a set of views of a step in the formation of a PCM device is shown. A top electrode 1302 is formed by etching a hole through the upper dielectric 1106 to expose the upper contact electrode 908. Conductive material may then be formed in the hole and may be polished down to the level of the upper dielectric 1106 to form the top electrode. During operation of this embodiment, current passes between the top electrode 1302 to the bottom wire 1002, through the PCM layer 902.

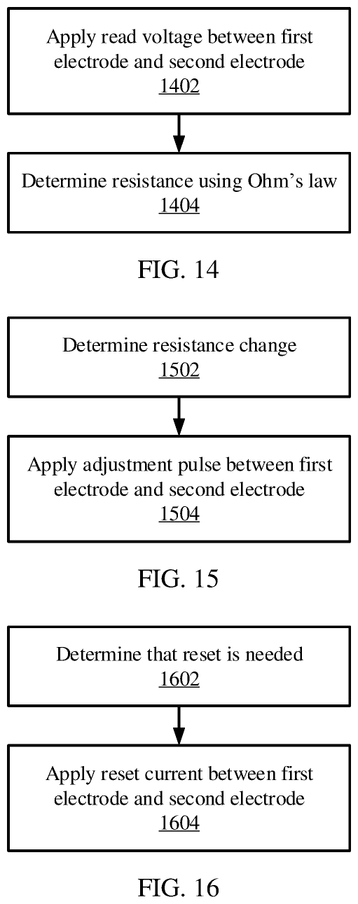

Referring now to FIG. 14, a method for reading a value stored in a PCM cell is shown. Block 1402 applies a read voltage between a first electrode and a second electrode. In some cases, this voltage may be applied between a contact wire 106 and a bottom electrode 202. In some cases, the read voltage may be applied between two contact wires 106. In other cases, the read voltage may be applied between a top wire 910 and a bottom wire 1002. It is specifically contemplated that the read voltage will be low enough that no change is caused to the phase state of the PCM cell.

Block 1404 then determines the resistance of the PCM cell using Ohm's law, which may be expressed as R=V/I. Thus, dividing the applied read voltage V by the current I that passes through the PCM cell gives the resistance value R. This resistance may correspond to a predetermined data value, for example with a high resistance value corresponding to a logical ‘one’ and with a low resistance value corresponding to a logical ‘zero.’ Intermediate values are also possible. For example, if the resistance range is divided into regions, then each region may correspond to a different binary sequence. In an example with four such regions, the possible data values may be ‘00, “01,”10,’ and ‘11.’

Referring now to FIG. 15, a method for altering a value stored in a PCM cell is shown. Block 1502 determines a resistance change that is needed. For example, if the cell is in a high-resistance state, and the value to be stored calls for a low-resistance state, block 1502 may determine a difference in the resistance to be effected.

Block 1504 then applies an adjustment voltage pulse between the first electrode and the second electrode. The adjustment voltage pulse may be larger than the read voltage pulse, and may cause a partial or total phase change of the PCM cell, for example from an amorphous phase to a crystalline phase. The duration of the pulse may determine how much of the PCM cell changes in phase, and thus may correspond to the determined resistance change.

Referring now to FIG. 16, a method for altering a value stored in a PCM cell is shown. Block 1602 determines that a reset of the resistance state is needed. For example, if the cell is in a low-resistance state, and the value to be stored calls for a high-resistance state, block 1602 may determine that the resistance state cannot be reached by incremental phase change adjustments and that a reset to an amorphous state is needed.

Block 1604 then applies a reset voltage pulse between the first electrode and the second electrode. The reset voltage pulse may be larger than the adjustment voltage pulse, and may return the PCM cell to an amorphous state.

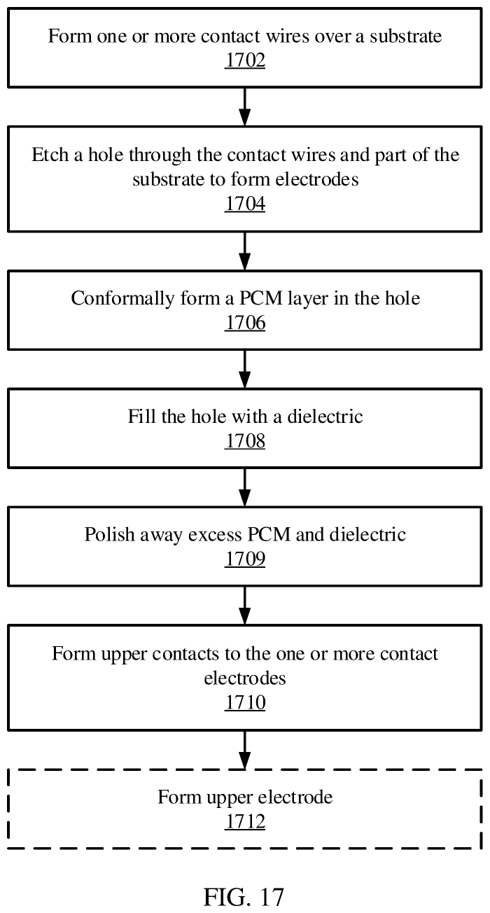

Referring now to FIG. 17, a method for forming a PCM cell is shown. Block 1702 forms one or more wires 302 over a substrate. In the embodiments of FIGS. 1-8, the substrate may include a bottom electrode 202 that is formed in a layer of dielectric material 204, or may be a dielectric layer 802 with a high thermal conductivity. The substrate may further include a layer of dielectric material over the bottom electrode 202 or thermal sink layer 802. Formation of the wires 302 may include depositing a layer of conductive material and patterning the layer using any appropriate photolithographic process.

Block 1704 etches a hole 402 through the wires 302 and parts of the substrate to expose, e.g., the bottom electrode 202 or the thermal sink layer 802. The hole 402 may be formed by any appropriate anisotropic etch process, such as an RIE, using a photolithographically patterned mask. The hole 402 cuts into the wire(s) 302, forming contact electrodes 108.

Block 1706 conformally deposits PCM in the hole 402 using any appropriate conformal deposition process, such as CVD. Block 1708 then fills the remainder of the hole 402 with a dielectric material. Block 1709 polishes down the PCM and the dielectric material to form PCM layer 102 and dielectric structure 104. Block 1710 then forms upper wires 106 to meet the contact electrodes 108, for example by etching down through a passivating dielectric layer and depositing conductive material.

In some embodiments, an upper electrode may be formed over the PCM layer 102. The upper electrode may be formed along with the upper contacts, for example etching down through the passivating dielectric layer in a region over the PCM layer 102 and depositing conductive material that makes contact with a top surface of the PCM layer 102.

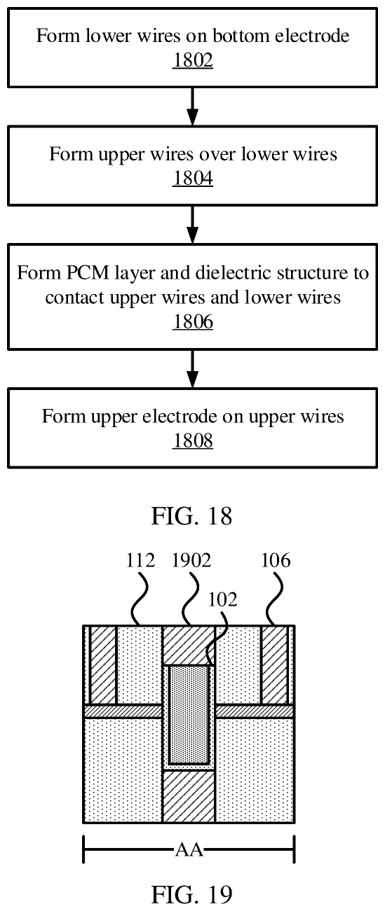

Referring now to FIG. 18, a method for forming a PCM cell is shown. Block 1802 forms lower electrodes 906 on a bottom wire 1002, for example by forming a mask 1004 using a photolithographic process, depositing a conductive material, and polishing down to the level of the mask 1004 using a CMP process. Block 1804 then forms upper electrodes 908 over the lower electrodes 906, for example by depositing a layer of dielectric material over the lower electrodes 906, and then forming an upper mask 1104 that is used to define the location for the conductive material of the upper conductive electrodes 908. Block 1806 forms a PCM layer 902 and a dielectric structure 904 by forming a hole that exposes end surfaces of the lower electrodes 906 and the upper electrodes 908. Block 1806 conformally deposits PCM in the hole and then fills the hole with a dielectric material, followed by a CMP process to remove excess material from the top surface. Block 1808 forms an upper wire 910 on the upper electrodes 908 by etching a hole through any overlying dielectric material and depositing conductive material in the hole.

Referring now to FIG. 19, a cross-sectional view of an alternative embodiment, along plane AA, is shown. In some cases, a top electrode 1902 may be formed over the PCM layer 102, making electrical contact therewith, as in FIG. 17, block 1712. The top electrode 1902 may be formed from any appropriate conductive material.

In such embodiments, read and write currents may be established between one of the top/bottom electrodes and one of the side electrodes to form a memory cell. For example, the left-side electrode and the bottom electrode may form one memory cell, while the right-side electrode and the top electrode may form a second memory cell.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ, where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as dwell, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one elements or feature's relationship to another element(s) or feature(s) as illustrated in the FIGS. It will be understood that the spatially relative: terms are intended to encompass different orientations of the device in use or operation addition the orientation depicted in the FIGS. For example, if the device in the FIGS. is turned over, elements described as “below” or “beneath” other elements or features would then be oriented “above” the other elements or features. Thus, the term below can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of a vertical ultra-thin PCM cell (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of forming a memory cell includes, comprising:
forming a hole in an interlayer dielectric to expose an end of a conductive top electrode;
conformally depositing a phase change material on surfaces of the hole; and
filling a remaining portion of the hole with a dielectric material after conformally depositing the phase change material.

2. The method of claim 1, wherein forming the hole exposes an underlying bottom electrode, and wherein conformally depositing the phase change material deposits phase change material in electrical contact with the bottom electrode.

3. The method of claim 1, wherein forming the hole exposes an underlying thermal sink layer.

4. The method of claim 1, wherein forming the hole cuts the conductive top electrode into two top contact electrodes, and wherein conformally depositing the phase change material deposits phase change material in electrical contact with exposed surfaces of the two top contact electrodes.

5. The method of claim 1, further comprising forming an upper wire in electrical contact with the conductive top electrode.

6. The method of claim 1, wherein the phase change material is selected from the group consisting of GeSbTe in any appropriate proportions, SiGeSbTe in any appropriate proportions, Sb₂Te₃, GeTe, and Cr₂Ge₂Te₆.

7. The method of claim 1, wherein the interlayer dielectric is formed from a distinct material compared to the dielectric material.

8. The method of claim 1, further comprising:
forming a bottom electrode on a bottom wire; and
forming the conductive top electrode over the bottom electrode, before forming the hole, wherein forming the hole exposes an end of both the bottom electrode and the conductive top electrode.

9. A semiconductor device, comprising:
a phase change material liner beneath, and laterally surrounding, a dielectric core;
a first electrode in contact with the phase change material liner; and
a second electrode in contact with the phase change material liner.

10. The memory cell of claim 9, wherein the first electrode and the second electrode are on a same horizontal plane.

11. The memory cell of claim 9, wherein the first electrode is positioned closer to the top surface than the second electrode.

12. The memory cell of claim 11, further comprising a bottom wire under the second electrode and a top wire over the first electrode.

13. The memory cell of claim 9, further comprising a bottom electrode under the phase change material liner, in contact with the phase change material liner.

14. The memory cell of claim 9, further comprising a thermal sink layer under the phase change material liner.

15. The memory cell of claim 9, wherein the first electrode has a first interface area with the phase change material liner that is smaller than a second interface area between the second electrode and the phase change material liner.

16. The memory cell of claim 15, further comprising:
a third electrode in electrical contact with a side of the phase change material liner opposite to the first electrode, having a third interface area with the phase change material liner that is a same size as the first interface area; and
a fourth electrode in electrical contact with a side of the phase change material liner opposite to the second electrode.

17. The memory cell of claim 9, further comprising an interlayer dielectric around the phase change material liner, formed from a different material compared to the dielectric core.

18. A memory cell, comprising:
a phase change material liner beneath, and laterally surrounding, a dielectric core;
a dielectric layer around the phase change material liner; and
a first electrode in electrical contact with phase change material layer.

19. The memory cell of claim 18, further comprising a bottom electrode under the phase change material layer, in electrical contact with the phase change material liner.

20. The memory cell of claim 17, wherein the dielectric core is formed from a different material compared to the dielectric layer.
